(19) United States
(12) Patent Application Publication
(10) Pub. No.: US 2008/0296717 A1
(43) Pub. Date: Dec. 4, 2008

(54) Packages and assemblies including lidded chips

(75) Inventors: Masud Beroz, San Jose, CA (US); Belgacem Haba, Saratoga, CA (US); Michael J. Nystrom, San Jose, CA (US); Richard Dewitt Crisp, Castro Valley, CA (US); Giles Humpston, Aylesbury (GB)

Correspondence Address: TESSERA;LERNER DAVID et al., 600 SOUTH AVENUE WEST, WESTFIELD, NJ, 07090, US

(73) Assignee: Tessera, Inc., San Jose, CA (US)

(21) Appl. No.: 11/809,780

(22) Filed: Jun. 1, 2007

(51) Int. Cl. H01L 31/0203; H01L 21/58; H01L 23/02

(52) U.S. Cl. 257/434; 257/704; 438/118; 257/E31.11; 257/E23.18; 257/E21.505

(57) ABSTRACT

A lidded chip is provided which includes a chip having a major surface and a plurality of first chip contacts exposed at the major surface. A lid overlies the major surface. A chip carrier is disposed between the chip and the lid, the chip carrier having an inner surface confronting the major surface and an outer surface confronting the lid. A plurality of first carrier contacts of the chip carrier are conductively connected to the first chip contacts. A plurality of second carrier contacts extend upwardly at least partially through the openings in the lid.

### BACKGROUND OF THE INVENTION

The present invention relates to microelectronic packaging. Microelectronic chips typically are thin, flat bodies with oppositely facing, generally planar front and rear surfaces and with edges extending between these surfaces. Chips generally have contacts on the front surface, which are electrically connected to the circuits within the chip. Certain chips require a protective element, referred to herein as a cap, lid or cover, over all or part of the front surface. For example, chips having optoelectronic devices, e.g., image sensors or light emitting devices and the like incorporate optically active regions on their front surfaces, which are best protected from physical and chemical damage by a cap, lid or cover. Often, the cap, lid or cover overlies a cavity above the active region of the chip.

Certain other types of devices such as microelectromechanical or “MEMS” chips include microscopic electromechanical devices, e.g., acoustic transducers such as microphones or surface acoustic wave (“SAW”) filters, which must be covered by a cap. The caps used for MEMS and SAW chips must be spaced from the front surface of the chip to an open gas-filled or vacuum void beneath the cap in the active area, so that the cap does not touch the acoustical or mechanical elements. Voltage controlled oscillators (VCOs) sometimes also require a cap to be placed over the active area.

Desirably, protective elements such as caps, lids or covers are added to such units by processing which is efficient and which provides reliable protection for the sensitive devices early in the packaging process. For example, protective elements can be provided for each chip by wafer level processing in which, for example, a lid wafer is assembled with a device wafer containing multiple chips which remain attached together. The assembled wafers can then be cut into individual units each containing a chip and a lid overlying the chip.

### SUMMARY OF THE INVENTION

In accordance with an aspect of the invention, a lidded chip is provided which includes a chip having a major surface. Desirably, a plurality of first chip contacts are exposed at the major surface. A lid is provided such that it desirably overlies the major surface. A chip carrier is disposed between the chip and the lid. Desirably, an inner surface of the chip carrier confronts the major surface, such that an outer surface confronts the lid. A plurality of first carrier contacts of the chip carrier can be conductively connected to the first chip contacts, and a plurality of second carrier contacts can extend upwardly from a surface of the chip carrier, e.g., the outer surface, such that the second carrier contacts extend at least partially through the openings in the lid.

The chip can include an active region having an optoelectronic device. The lid may be at least partially transmissive to radiation at frequencies of interest to the optoelectronic devices or may be transparent to such radiation, e.g., light.

The chip carrier may have an opening permitting transmission of radiation at frequencies of interest between the major surface and a space above the chip carrier. A standoff structure may be provided for supporting an inner surface of the lid a distance from the major surface. In such way, a cavity may be defined between the inner and major surfaces.

Lateral dimensions of the major surface of the chip are desirably at least substantially the same as lateral dimensions of the lidded packaged chip. Second carrier contacts of the chip carrier may include metallic posts such that tips of the posts protrude above the outer surface of the lid. In an assembly including the lidded chip, a circuit panel can have terminals conductively joined to the exposed tips of the posts. In a particular embodiment, an inner surface of the lid may be bonded to the outer surface of the chip carrier.

In a lidded chip assembly in accordance with another embodiment of the invention, a chip is provided which has a major surface on which an active region including an optoelectronic device is desirably aligned with the major surface. Desirably, a plurality of contacts are exposed at the major surface. A lid overlies the active region. The lid has an inner surface confronting the major surface of the chip, an outer surface remote from the inner surface. Desirably, a plurality of through holes extend between the inner and outer surfaces. A plurality of conductive package interconnects may extend at least partially through the through holes. An interconnection element is typically included in the lidded chip assembly. Desirably, the interconnection element includes horizontal metal elements connected to the package interconnects and metal posts connected to the horizontal metal elements. The interconnection element may be disposed between the lid and the major surface. The horizontal metal elements may extend along the inner surface of the lid, such as, for example, for interconnecting the horizontal metal elements to the contacts on the chip. Typically, the horizontal elements include conductive traces extending along the interconnection element, although other types of horizontal conductive elements can be provided.

In accordance with another embodiment of the invention, a lidded chip is provided which includes a chip including an active region, the active region having an optoelectronic device, for example. The chip has a major surface and edges which extend away from the major surface. Desirably, a plurality of contacts are exposed at the major surface. A lid overlies the chip, the lid desirably having an inner surface which confronts the major surface of the chip. The lidded chip may further include an interconnection element having a dielectric layer, and lands exposed beyond the edges of the chip. Conductive traces may extend from the lands along the dielectric layer. Desirably, metal posts conductively connect the conductive traces to the contacts on the chip. A plurality of conductive metal bumps desirably extend from the lands away from the inner surface of the lid.

In accordance with another embodiment of the invention, a lidded chip is provided which includes a chip having a major surface, and desirably, an active region including an optoelectronic device at the major surface. Desirably, a plurality of chip contacts are provided at the major surface. A lid overlies the active region. An inner surface of the lid confronts the major surface of the chip. A plurality of package interconnects can be provided which are exposed at an exterior surface of the lidded chip. An interconnection element may be disposed between the inner surface of the lid and the major surface of the chip. Such interconnection element may include horizontal metal elements in conductive communication with the contacts and the package interconnects.

In a particular embodiment, the chip includes a plurality of active regions and the interconnection element includes a plurality of openings aligned with the active regions. The lid may further include through holes extending between the inner and outer surfaces. The package interconnects may extend from at least some of the chip contacts at least partially through the through holes.

Some or all of the chip contacts may be exposed beyond edges of the lid. The package interconnects may include some or all of the exposed chip contacts.

Some or all of the chip contacts may be exposed within recesses in edges of the lid. The package interconnects may include some or all of the exposed chip contacts.

In a particular embodiment, the lid may include through holes extending between the inner and outer surfaces and the package interconnects may be disposed adjacent to peripheral edges of the chip. For example, the package interconnects may be provided such that they extend from at least some of the chip contacts at least partially through the through holes.

In accordance with another aspect of the invention, a lidded microelectronic assembly is provided which includes a microelectronic element having a major surface, a first active region and a second active region at the major surface. First conductive pads are desirably provided, the first conductive pads being conductively connected to the first active region. Second conductive pads are desirably conductively connected to the second active region. A lid desirably overlies the first and second active regions. The lid has an inner surface which confronts the major surface. An outer surface of the lid is remote from the inner surface. Desirably, a plurality of through holes extend between the inner and outer surfaces. The assembly can include a plurality of package interconnects extending from the first and second conductive pads at least partially through the through holes. An interconnect element may overlie the lid, the interconnect element desirably including a dielectric element having a first surface confronting the lid, a second surface remote from the first surface, a plurality of first contacts at the first surface joined to the plurality of package interconnects, a plurality of second contacts exposed at the second surface, and a plurality of conductive traces extending along the first surface.

The conductive traces and the package interconnects of the lidded microelectronic assembly desirably connect the first conductive pads with the second conductive pads.

The package interconnects can include metallic posts extending downwardly from the first surface. The lidded microelectronic assembly may further include a second microelectronic element having third contacts. The third contacts may be conductively connected to the second contacts. Bond wires may conductively connect the third contacts to the second contacts.

Desirably, a front face of the second microelectronic element confronts the second surface of the interconnect element. A fusible metal may conductively connect the second and third contacts.

The first and second active regions may include optoelectronic devices. In such case, desirably, the lid is at least partially transmissive to radiation at frequencies of interest to the optoelectronic devices. The optoelectronic devices in at least one of the first or second active regions may include imaging sensor. The assembly may further include an optical element aligned with at least one of the first or second active regions.

The lid may include openings which are aligned with the first and second active regions.

In accordance with one or more aspects of the invention, a lidded microelectronic assembly is provided which includes a microelectronic element having a major surface. Desirably, a first active region and a second active region are provided at the major surface. First conductive pads can be provided, the first conductive pads being conductively connected to the first active region. Second conductive pads may be conductively connected to the second active region. Desirably, at least one lid overlies the first and second active regions. Desirably, the lid has an inner surface confronting the major surface, an outer surface remote from the inner surface and at least one channel extending between the inner and outer surfaces. Desirably, the channel exposes the first conductive pads and the second conductive pads. An interconnect element can be provided overlying the lid. Desirably, the interconnect element includes a dielectric element having a first surface remote from the lid, a second surface confronting the lid, and a plurality of first contacts conductively connected to the first and second conductive pads. The interconnect element may include a plurality of second contacts, and a plurality of conductive traces can be provided thereon or therein which extend parallel to the first surface. The conductive traces may connect the first and second contacts, for example.

In a lidded microelectronic assembly in accordance with an embodiment of the invention, the first and second contacts may be exposed at the first surface, and the lidded microelectronic assembly may further include bond wires. The bond wires may be used to conductively connect the first contacts to the first and second conductive pads.

The interconnect element may include locating features, such as protrude downwardly, for example, between the second surface and the outer surface of the lid. The locating features may include metallic posts, for example. The locating features may in some cases be bonded to the outer surface of the lid. The first contacts may include conductive features which extend downwardly between the second surface and the first and second conductive pads. For example, the first contacts may include metallic posts.

In a lidded microelectronic assembly in accordance with one or more aspects of the invention, a first microelectronic element has a major surface, an active region at the major surface and first conductive pads exposed at the major surface. Desirably, a lid overlies the active region, the lid having an inner surface confronting the major surface and an outer surface remote from the inner surface. The lid may have a plurality of through holes extending between the inner and outer surfaces. The lid may further have an opening extending between the inner and outer surfaces. A plurality of conductive interconnects may extend upwardly from the conductive pads at least partially through the through holes. A second microelectronic element can be provided which includes a rear face confronting the first microelectronic element within the opening. The second microelectronic element has a front face remote from the rear face and may have second conductive pads at the front face. The second conductive pads can be conductively connected to the conductive interconnects.

A plurality of lid contacts may be exposed at the outer surface of the lid. Conductive traces can be provided which connect the lid contacts to the conductive interconnects. Bond wires may conductively connect the second conductive pads to the lid contacts.

In accordance with an aspect of the invention, a lidded microelectronic assembly is provided which includes a first microelectronic element having a major surface, an active region at the major surface and first conductive pads exposed at the major surface. A lid overlies the active region, the lid having an inner surface confronting the major surface, an outer surface remote from the inner surface and edges extending between the inner and outer surfaces. The lid may further include lid contacts exposed at the outer surface. An opening may extend between the inner and outer surfaces. A plurality of recesses may be provided in at least one edge which exposes at least ones of the first conductive pads. A second microelectronic element may have a rear face confronting the first microelectronic element within the opening, and a front face remote from the rear face. Second conductive pads may be provided at the front face. Desirably, the first and second conductive pads are conductively connected to the lid contacts.

The lidded microelectronic assembly may further include bond wires which conductively connect the first and second conductive pads to the lid contacts. The lid contacts may include first lid contacts and second lid contacts, and the bond wires may include first bond wires and second bond wires. The first bond wires can conductively connect the first conductive pads to the first lid contacts and the second bond wires can conductively connect the second conductive contacts to the second lid contacts. The lidded microelectronic assembly may further include conductive traces connecting the first lid contacts to the second lid contacts.

In accordance with an aspect of the invention, a method is provided for fabricating a lidded packaged chip. In such method, a chip carrier can be assembled with a semiconductor chip to form a chip carrier assembly such that the chip carrier overlies a major surface of the chip. A plurality of first chip contacts of the chip can be conductively connected to a plurality of first carrier contacts of the chip carrier. In such packaged chip, the chip carrier can include a plurality of second conductive contacts protruding above a surface of the chip carrier remote from the chip. A lid may be mounted to the chip carrier assembly such that tips of the plurality of second conductive contacts protrude upwardly through openings in the lid. The tips of the second conductive contacts may be exposed above an outer surface of the lid remote from the chip carrier.

In mounting the lid to the chip carrier assembly, an inner surface of the lid may be supported a predetermined distance above the major surface of the chip.

In accordance with one or more particular aspects of the invention, second carrier contacts may include metallic posts such that tips of the posts protrude above the outer surface of the lid. The chip carrier may include a dielectric layer which defines a major surface. Each post of the plurality of posts may have a base proximate to the major surface and a tip remote from the base, such that the base occupies a first area in the plane of the major surface, and the tip occupies a second area in a plane parallel to the major surface. Desirably, the first area is greater than the second area. Each of the openings desirably occupies a third area greater than the second area and less then the first area. Desirably, the step of mounting the lid to the chip carrier assembly includes press-fitting the posts into the openings in the lid.

In accordance with one or more particular aspects of the invention, a surface of the chip carrier may be mounted to an inner surface of the lid with an adhesive. In one example, the surface of the chip carrier may be bonded to the inner surface of the lid before the chip carrier is assembled together with the chip.

### BRIEF DESCRIPTION OF THE DRAWINGS

FIG. 1A is a sectional view illustrating a lidded chip package in accordance with an embodiment of the invention.

FIG. 1B is a corresponding plan view of the lidded chip package shown in FIG. 1A.

FIG. 2A is a sectional view illustrating a lidded chip package in accordance with a variation of the embodiment of the invention shown in FIGS. 1A and 1B.

FIG. 2B is a magnified partial sectional view illustrating the lidded chip package shown in FIG. 2A.

FIG. 3 is a sectional view illustrating a sub-assembly including a lid in accordance with an embodiment of the invention.

FIG. 4 is a sectional view illustrating an assembly including a lidded chip package incorporating the sub-assembly shown in FIG. 3.

FIG. 5 is a sectional view illustrating a lidded chip package having bond wires in accordance with another embodiment of the invention.

FIG. 6 is a sectional view illustrating a lidded chip package in accordance with another embodiment of the invention.

FIG. 7 is a sectional view illustrating a lidded chip package in accordance with a variation of the embodiment of the invention shown in FIG. 6.

FIG. 8 is a corresponding plan view illustrating the lidded chip package shown in FIG. 7.

FIG. 9 is a sectional view illustrating a lidded chip package having downwardly facing exposed contacts in accordance with another embodiment of the invention.

FIG. 10A is a first sectional view, through line 10A-10A (FIG. 11), illustrating an assembly including multiple microelectronic elements in accordance with another embodiment of the invention.

FIG. 10B is a second sectional view, through line 10B-10B (FIG. 11), further illustrating the assembly shown in FIG. 10A.

FIG. 10C is an enlarged partial section view of the assembly illustrated in FIG. 10A.

FIG. 11 is a plan view of the assembly shown in FIGS. 10A and 10B.

FIG. 12A is a first sectional view, through line 12A-12A (FIG. 13), illustrating an assembly including multiple microelectronic elements in accordance with another embodiment of the invention.

FIG. 12B is a second sectional view, through line 12B-12B (FIG. 13), further illustrating the assembly shown in FIG. 12A.

FIG. 13 is a plan view of the assembly shown in FIGS. 12A and 12B.

FIG. 14 is a sectional view illustrating a lidded microelectronic element in accordance with another embodiment of the invention.

FIG. 15 is a plan view of the lidded microelectronic element shown in FIG. 14.

FIG. 16 is a sectional view illustrating a lidded microelectronic element in accordance with another embodiment of the invention.

FIG. 17 is a magnified partial sectional view further illustrating the lidded microelectronic element shown in FIG. 16.

FIG. 18 is a plan view of the lidded microelectronic element shown in FIGS. 16-17.

FIG. 19 is a sectional view illustrating an assembly including a lidded microelectronic element mounted to a circuit panel in accordance with another embodiment of the invention.

FIG. 20 is a plan view of the assembly shown in FIG. 19.

FIG. 21 is a sectional view illustrating an assembly including a lidded microelectronic element in accordance with another embodiment of the invention.

FIG. 22 is a plan view of the assembly shown in FIG. 21.

FIG. 23 is a sectional view illustrating an assembly including a lidded microelectronic element in accordance with another embodiment of the invention.

FIG. 24 is a sectional view illustrating an assembly including a lidded microelectronic element in accordance with another embodiment of the invention.

FIG. 25 is a plan view of the assembly shown in FIG. 24.

FIG. 26 is a sectional view illustrating an assembly including a lidded microelectronic element in accordance with another embodiment of the invention.

FIG. 27 is a plan view of the assembly shown in FIG. 26.

FIG. 28 is a sectional view illustrating a lidded microelectronic element in accordance with another embodiment of the invention.

FIG. 29 is a plan view of the lidded microelectronic element shown in FIG. 28.

FIG. 30 is a sectional view illustrating an assembly including a lidded microelectronic element shown in FIGS. 28-29.

FIG. 31 is a plan view of the assembly shown in FIG. 30.

FIG. 32 is a sectional view illustrating an assembly including a lidded microelectronic element in accordance with another embodiment of the invention.

FIG. 33 is a plan view of the assembly shown in FIG. 32.

FIG. 34 is a sectional view illustrating an assembly including a lidded microelectronic element in accordance with another embodiment of the invention.

FIG. 35 is a plan view of the assembly shown in FIG. 34.

### DETAILED DESCRIPTION

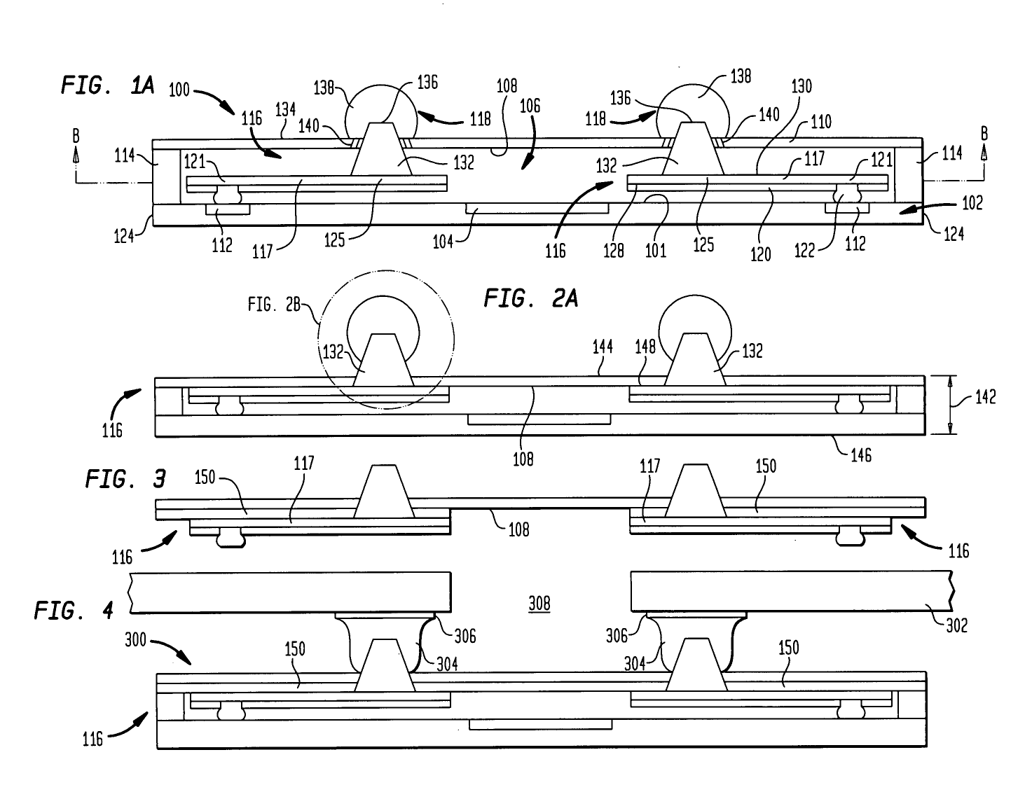

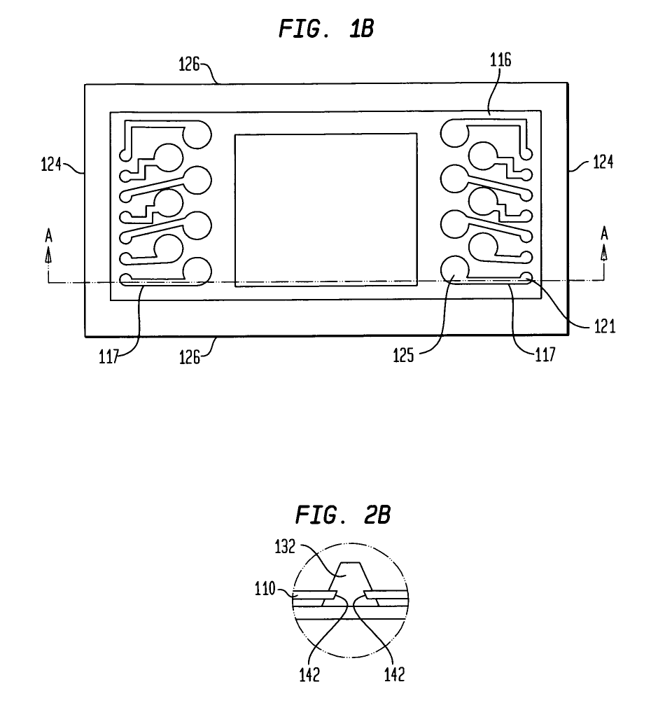

FIG. 1A is a sectional view illustrating a lidded chip package 100 in accordance with one embodiment of the invention. In this embodiment, a chip 102 is provided which includes a device 104, e.g., an optoelectronic device, micro-electromechanical system (MEMS) device, radio frequency transmitter or receiver or other device at the front surface 101 of the chip 102. Typically, the operation of the device 104 benefits from the protection of a lid 110 or cover. The following commonly owned United States patent applications and United States provisional patent applications are incorporated by reference herein; these applications describe various features of lidded chip packages, assemblies incorporating such packages and methods of fabricating the packages: Ser. No. 10/711,945; Ser. No. 10/928,839; Ser. No. 10/948,976; Ser. No. 10/949,575; Ser. No. 10/949,674; Ser. No. 10/949,693; Ser. No. 10/949,844; Ser. No. 10/949,847; Ser. No. 10/977,515; Ser. No. 11/016,034; Ser. No. 11/025,440; Ser. No. 11/068,830; Ser. No. 11/068,831; Ser. No. 11/120,711; Ser. No. 11/121,434; Ser. No. 11/204,680; Ser. No. 11/319,836; Ser. No. 11/322,617; 60/632,241; 60/664,129; and 60/707,813. The following commonly owned U.S. patents also describe various lidded chip packages and are incorporated by reference herein: U.S. Pat. Nos. 5,716,759; 5,547,906; 5,455,455; and 6,777,767.

When the chip includes an optoelectronic device, the lid desirably is either transparent to or is at least partially transparent to radiation, e.g., light, at wavelengths of interest, e.g., at wavelengths in visible, infrared or ultraviolet ranges or in a combination of such ranges. For example, for transparency in the visible wavelength range, the lid can consist essentially of glass. For example, the lid may include undoped or doped silicate glasses, quartz, polymers, certain metal oxides or other material transparent to visible light. On the other hand, when the chip includes an optoelectronic device which receives or emits infrared radiation or both, the lid can include another material such as silicon, among others, which is transparent to infrared wavelengths, even though such other material may not permit light of visible wavelength or other wavelengths to pass. Alternatively, when the device is a MEMs device or radio frequency device which does not need to transmit or receive radiation through the lid, the lid need not be especially transmissive. In fact, in the case of radio frequency devices, the lid 110 may need to provide electromagnetic shielding for the device 104. In such case, the lid may include or consist essentially of one or more metals, one or more conductive compounds of metals or both. When the lid consists essentially of a metal, e.g., copper, aluminum, silver, or other metal, for example, the lid can provide shielding for the device 104 from electric or magnetic fields external to the lidded chip. In addition, such metallic lid functions to shield other devices (not shown) disposed externally to the lidded chip from electric and magnetic fields generated by operation of the device 104.

As illustrated in FIG. 1A, the lid or cover encloses a space 106, e.g., a cavity or filled space between the device 104 at the front surface 101 and an inner surface 108 of the lid 110. In a particular embodiment, the lid 110 encloses a cavity in which a vacuum or gas is present. When a gas fills the cavity, the gas may be one such as argon or nitrogen which does not react or reacts at a slow rate, if at all, with materials exposed within the cavity. For particularly sensitive devices, e.g., surface acoustic wave (“SAW”) devices or the like, the lid may be sealed to the chip or other semiconductor element so as to form a hermetically sealed cavity above such device.

A feature of the embodiment shown in FIG. 1A is that both the device 104 and the contacts at the front surface of the chip 102 underlie the lid 110. Desirably, the contacts are enclosed within the same space 106 in which the device is enclosed. Support structure 114 is desirably provided which surrounds the chip contacts 112 and device 104, the support structure supporting the lid 110 above the front surface 101 of the chip 102.

Electrical interconnection between the chip contacts and external contacts 118 of the lidded chip is provided in accordance with a novel arrangement including an interconnect element 116. The interconnect element 116 can be variously referred to as an interposer, interconnect substrate, flexible circuit panel, or a “tape” typically having one or more metal layers, its function being to electrically interconnect the chip contacts 112 to external contacts 118 of the lidded chip 100. The interconnect element 116 includes a dielectric element 120 which desirably is capable of flexing under low to moderate stress or pressure. The dielectric element 120 can include a material such as polyimide or other polymeric material, for example. A metal layer disposed on one surface of the dielectric element includes a series of conductive traces 117.

From first pads 121, e.g., first ends of the traces 117, conductive bumps 122 including a fusible metal such as solder, tin or eutectic, extend downwardly from a lower surface 128 of the traces through the dielectric element 120 where the bumps 122 are joined to the contacts 112 of the chip 102. From other pads 125, e.g., second ends of the traces, conductive posts 132 extend upward from an upper surface 130 of the traces 112. The posts 132 extend upward at least partially through corresponding openings in the lid 110. Desirably, top surfaces 136 of the conductive posts extend above the top or “outer” surface 134 of the lid 110. The conductive posts 132 typically are solid metal features which consist essentially of one or more metals such as copper, nickel, platinum, palladium, aluminum, silver or other noble metal. Desirably, the posts consist essentially of one or more metals which has a melting temperature higher than that of a fusible metal 138 which may be provided on external surfaces of the posts for interconnection to other microelectronic elements, e.g., a circuit panel.

Typically, the conductive posts are formed by processing done prior to assembly of the interconnect element 116 to the chip 102 and lid 110. Desirably, the conductive posts can be formed by a subtractive process of etching a metal layer in accordance with a stencil or photolithographically defined photoresist patterns, e.g., by a process such as that described in commonly owned U.S. Pat. No. 6,826,827 to Fjelstad et al., or U.S. Pat. No. 6,528,874 to Iijima et al., the disclosures of which are hereby incorporated herein. Alternatively, the conductive posts can be formed by an additive process of plating a metal within predefined openings in a patterned photoresist layer or dielectric layer, as also described in the above-referenced incorporated U.S. patents. In another variation, the conductive posts 132 are solid metal conductive stud bumps formed as by a wire-bonding tool or tool designed specifically for forming stud bumps.

FIG. 1B illustrates a corresponding plan view of the interconnect element 116, as taken through line B-B of FIG. 1A. The left and right edges of the chip are illustrated at 124, and the top and bottom edges of the chip are illustrated at 126. Pads 121 and 125, from which the conductive bumps and conductive posts extend, are further illustrated in plan view in FIG. 1B.

As further shown in FIG. 1A, a layer including a metal wettable by a fusible metal such as solder overlies walls of the openings in the lid 110. The external contacts 118 of the lidded chip protrude above the top or “outer” surface 134 of the lid 110 and desirably include masses of a fusible metal 138 joined to the conductive posts 132. In such case, the masses 138 of fusible metal typically are joined to the wettable metal layer 140, forming a seal at the upper surface 134 of the lid 110. Sealing the openings in the lid by masses 138 of fusible metal joined to the conductive posts 132 as shown in FIG. 1A can help provide hermeticity, when the material of which the lid 110 and support structure 114 are appropriately nonporous and form an appropriately hermetic seal.

Typically, lids made of glass, metal, silicon or other semiconductor material provide a greater degree of impenetrability than lids made of polymeric material. To help achieve hermeticity, the support structure 114 may also consist essentially of metal, glass, silicon or other semiconductor material. In a particular embodiment, the lid 110 and support structure 114 may be provided as one unitary member having uniform composition of metal, glass, silicon, or other semiconductor material, in which the cavity 106 is provided as a recessed portion within the unitary member. However, the lid and the support structure need not be of the same material. For example, a metallic support structure can be used to both support and seal a glass, semiconductor or metal lid 110 above the front surface 101 of the chip. A glass support structure, formed, for example, by a low melting temperature glass can be used to support and seal lids having glass, semiconductor or metal composition. Even a support structure consisting essentially of semiconductor material can be used to support and seal a metallic lead to a corresponding metal feature such as a seal ring at the front surface of the chip.

On the other hand, certain other devices do not require hermetic seals. Most optoelectronic devices, such as imaging devices, e.g., charge-coupled device (“CCD”) arrays, are protected from spoilage by a lid from dust and other contamination, but usually do not need to be enclosed in hermetically sealed packages. In such case, the external contacts 118 may not even need to form a seal with the openings in the lid at the conductive posts. When the openings do not require seals, the wettable metal layer 140 also may not need to be provided on walls of the openings in the lid.

FIG. 2A illustrates a variation of the embodiment described above with reference to FIGS. 1A-B. In this variation, the conductive posts 132 of the interconnect element 116 are fitted under pressure into the openings in the lid 110 such that the posts fit snugly in the openings. Heat may be applied when fitting the interconnect element onto the lid, which typically will be done before joining the interconnect element to the chip. When press-fitted to the lid under appropriate temperature and pressure, the posts may even deform somewhat at edges of the openings. When that is the case, the posts may appear to be “riveted” or locked in the openings of the lid as illustrated in the fragmentary view of FIG. 2B. In that case, the posts may form a seal with the edges of the openings, contributing to the hermetic sealing of the cavity 106 within.

In addition, when the posts 132 are press-fitted into the openings, it may be possible to obtain a packaged device having a lower profile, i.e., a smaller thickness 142 in a direction from the outer surface 144 of the lid 110 to a rear surface 146 of the chip. The decreased thickness results because the distance between an outer surface 148 of the metal layer 117 and an inner surface 108 of the lid is reduced or eliminated.

FIG. 3 illustrates another variation of the embodiment illustrated in FIG. 1, in which the outer surface 148 of the metal layer 117 of the interconnect element 116 is joined to the inner surface 108 of the lid by way of an adhesive 150. With the adhesive 150 so placed, the interconnect element can be held more firmly to the lid, to reduce or eliminate flexing of the interconnect element. In addition, the adhesive can help seal the openings in the lid through which the conductive posts extend. In addition, another potential benefit that can be achieved by the adhesive is to keep dissimilar metals apart to avoid electromigration, as when the lid has a metal exposed at its inner surface 108 or within the lid openings 152 which is dissimilar from a metal included in the metal layer of the interconnect element. FIG. 4 illustrates a lidded chip 300 which includes the interconnect element 116 joined to the lid 110 by an adhesive 150, in accordance with the embodiment of the invention illustrated in FIG. 3. FIG. 4 additionally illustrates interconnection of the lidded chip to a circuit panel 302. Masses 304 of flowable conductive material, e.g., a fusible metal such as solder, tin or eutectic composition, join the conductive posts 132 to terminals 306 exposed at a lower surface of the circuit panel. The circuit panel 302 may also include an opening 308 in registration with the active region 104 or aligned with the active region to permit passage of radiation, e.g., imaging light, to or from the active region or both.

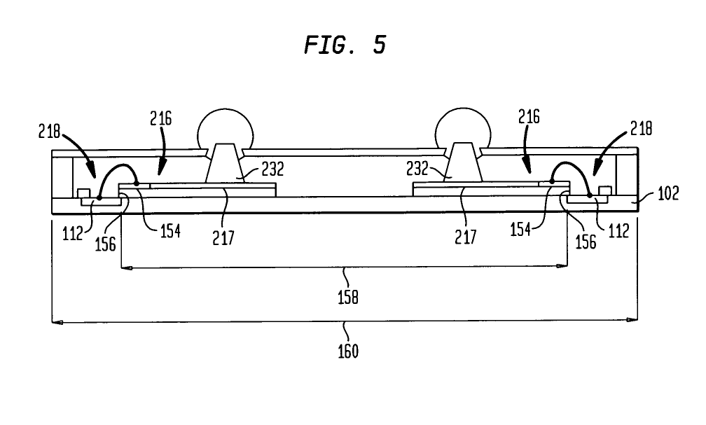

FIG. 5 illustrates a variation of the embodiment of the invention discussed above with reference to FIG. 1. In this variation, contacts 112 of the chip are wire-bonded to conductive lands 154 of the interconnect element 216 and the lands 154 are conductively connected to the posts 232 by way conductive traces 217. The contacts 112 of the chip are exposed by openings 218 in the interconnect element, and the bond wires extend from the contacts through the openings 218 to the lands 154.

As seen in FIG. 5, the dielectric element of the interconnect element 216 rests on the front surface 101 of the chip in this “circuits out” arrangement. Alternatively, the front surface of most chips typically includes a dielectric passivation layer, in a circuits in arrangement, the interconnect element can be placed on the front surface of the chip with the lands and traces of the metal layer facing the front surface of the chip. First openings will be provided in the dielectric layer through which the conductive posts will extend upwardly towards the openings in the lid. Second openings can be provided in the dielectric layer through which the bond wires contact the lands.

In another variation of the embodiment illustrated in FIG. 5, the lateral width 158 of the interconnect element in horizontal directions is decreased such that the edges of the interconnect element are located approximately where walls 156 of the opening are shown in FIG. 5. At least portions of the contacts 112 are exposed beyond the peripheral edges of the interconnect element to permit attachment of the bond wires.

In yet another variation, the width of the interconnect element can be greater such that the interconnect element extends the entire width 160 of the chip 102 in the direction shown. In a particular embodiment, the interconnect element desirably extends across the entire width of the chip in at least one lateral direction when the assembly illustrated in FIG. 5 is formed by a wafer-level manufacturing method, for example, using a tape with conductive patterns thereon which extends in such lateral direction across more than one chip. After joining such tape to a wafer or portion thereof containing several chips, the wafer or portion thereof is diced or cleaved, i.e., severed into individual units of the width 160 shown in FIG. 5. Wire-bonding between the contacts and the lands can be performed either before or after severance into chips.

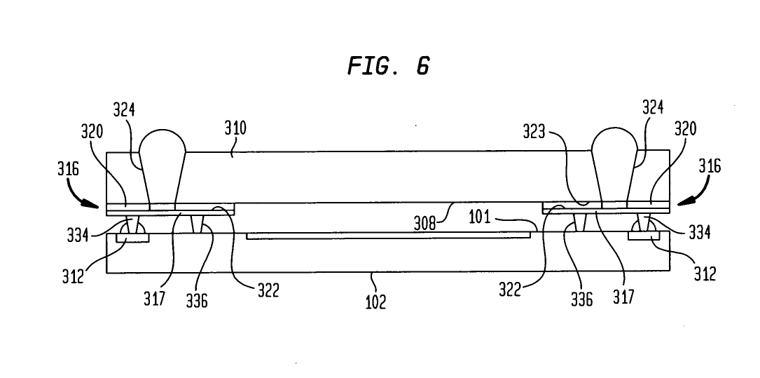

In the embodiment illustrated in FIG. 6, an interconnect element 316 is attached to the inner surface 308 of the lid 310 in a “circuits-in” arrangement, with the dielectric layer 320 of the interconnect element facing the inner surface and the metal layer 317 facing the front surface 101 of the chip. First conductive posts 336 extend downwardly from the metal layer 317 toward the front surface 102 of the chip where they are mechanically and conductively joined to contacts 312 of the chip via a fusible metal such as solder, tin or a eutectic metal composition. Second conductive posts 336 extend downwardly from the metal layer 317 towards the front surface 101 of the chip, the second posts 336 supporting the interconnect element 317 and lid 310 joined thereto above the front surface 101 of the chip. In a particular embodiment, the second posts space the metal layer of the interconnect element from the front surface of the chip. External interconnection to the chip is provided through conductive interconnects 326 which extend from a top surface 322 of the metal layer 317 upwards through through holes 324 in the lid 310. The conductive interconnects can be formed, for example by one or more methods such as those described in commonly owned U.S. patent application Ser. No. 10/949,674 filed Sep. 24, 2004, the disclosure of which is hereby incorporated by reference herein.

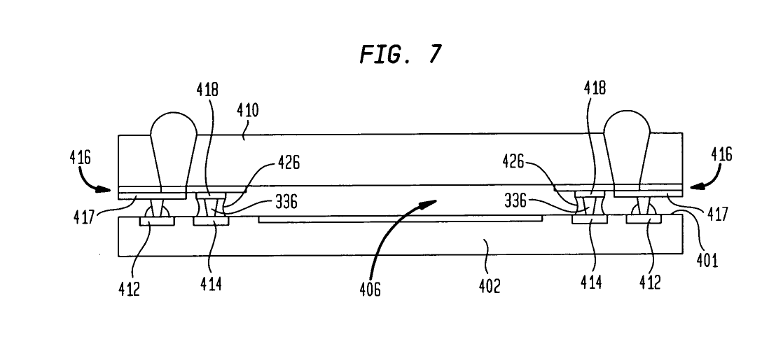

FIG. 7 illustrates a variation of the embodiment shown and described above with respect to FIG. 6, in which a sealing medium 426, e.g., a ring of fusible metal, e.g., solder, tin, eutectic, etc. is provided on the front surface 401 of the chip 402, fixedly joining the interconnect element 416 to the chip 402 and sealing the front surface of the chip to the interconnect element. Desirably, the sealing medium is joined to a wettable ring of 414 exposed at the front surface 401 of the chip, the wettable ring including a wettable metal such as tin, gold, copper, aluminum or the like to which the fusible metal readily adheres and fuses when molten. As in the above-described embodiment (FIG. 6), second conductive posts 336 space the metal layer from the front surface 401 of the chip. The second conductive posts may also provide a “wicking” function on which the fusible metal when molten travels upward from the wettable ring 414 on the chip and meets a corresponding ring 418 provided in the metal layer 417 of the interconnect element 416. The locations of the contacts 412 of the chip are also apparent in FIG. 7, these being disposed laterally to the outside of the sealing medium, such that the sealing medium fully encloses and seals the device 404 within a cavity 406 underlying the lid 410.

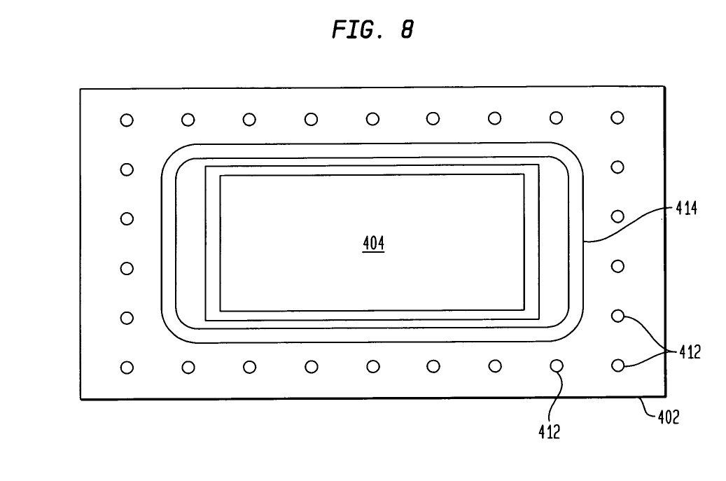

FIG. 8 shows a plan view of the chip 402, the placement of the wettable metallic ring 414 enclosing the microelectronic, electro-optic or electromechanical device 404 of the chip, and the placement of the contacts 412 laterally outside of the ring 414.

As noted above, the metal layer of the interconnect element illustrated in FIGS. 6 and 7-8 has a “circuits-in” configuration. Namely, the traces 317 and contacts of the interconnect element 316 are provided at a lower surface 322 of the dielectric layer 320 and face the front surface 101 of the chip. In a variation of the embodiments illustrated in FIGS. 6 and 7-8, the positions of the metal layer and dielectric element of the interconnect element can be reversed to provide a “circuits-out” arrangement in which the metal layer is provided at an upper surface 323 (FIG. 6) of the dielectric layer 320, the metal layer facing towards the lid rather than towards the front surface of the chip.

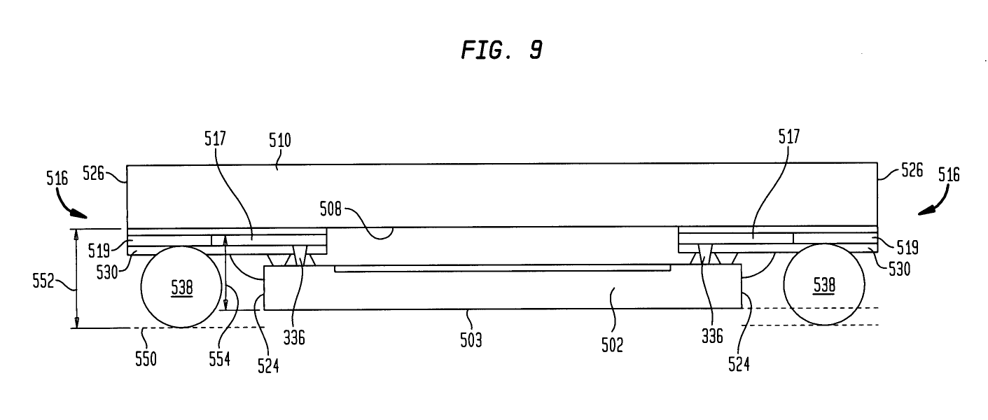

FIG. 9 illustrates a variation of the embodiment shown in FIG. 6 in which the lid 510 has peripheral edges 526 which extend beyond peripheral edges 524 of the chip. The interconnect element 516 includes traces 517 which extend beyond the edges 524 of the chip in a direction from the posts 336 to wettable conductive lands 519 or pads which downward from the interconnect element 516. A solder mask 530 desirably overlies the conductive lands and traces so as to passivate the lands and traces except for areas where the conductive masses and posts 336 connect.

Conductive masses 538 are attached to the lands. The conductive masses include, for example, solder balls or bumps of fusible conductive material, other conductive material, or a combination of fusible and other conductive material. The conductive masses may include nonconductive elements as well, such as polymeric cores, etc., which may be coated with conductive, e.g., fusible or nonfusible metals, or combination of such. The conductive masses extend downward such that surfaces of the masses define a reference plane 550 which lies at a greater distance from the lower surface 508 of the lid 510 than the distance of the rear surface 503 of the chip 502 from that lower surface 508.

The structure illustrated in FIG. 9 can assembled in a variety of ways. In one way, features of the interconnect element are formed by applying an interconnect element to the lid or applying films of the interconnect element to the lid, after which the contacts of the chip are joined to the contacts of the interconnect element. The conductive masses 538, e.g., solder balls, can be applied after the chip is joined to the interconnect element, either before or after the interconnect element 516 is joined to the lid. This way provides protection to the chip from possible contamination during the process of joining the conductive masses to the interconnect element.

Alternatively, when contamination concerns are not as great, the conductive masses 538 be applied to the interconnect element after the interconnect element is joined to the lid but before the chip is joined to the interconnect element.

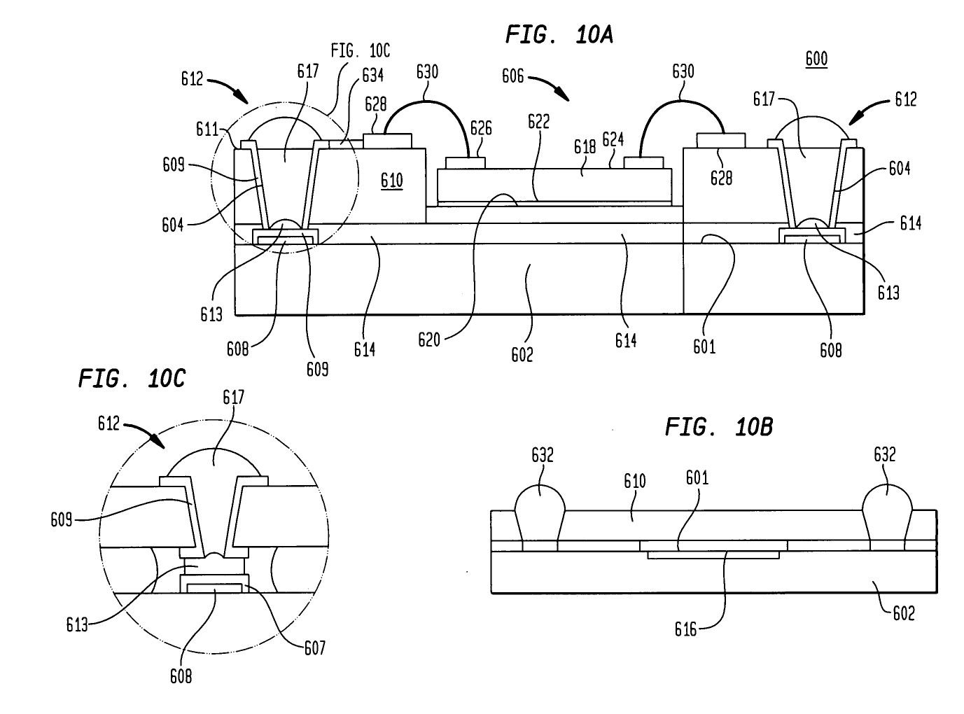

In a lidded chip assembly 600 (FIGS. 10A-B) according to another embodiment, a lid 610 is mounted to a base chip 602 or element of a wafer. The lid includes through holes 604 through which conductive interconnects 612 extend from contacts 608 on the chip upwardly through the through holes 604, similar to that described in U.S. application Ser. No. 10/949,674 filed Sep. 24, 2004, the disclosure of which is hereby incorporated herein by reference. As described in that incorporated application, at least some steps in the fabrication of the lidded chip package 600 are performed at wafer scale, i.e., by joining a lid wafer, or portion thereof to a corresponding device wafer or portion thereof, forming conductive interconnects 612, and then severing the resulting assembly into individual lidded chip packages. As further illustrated in FIG. 10A and as shown in the magnified view thereof in FIG. 10C, the conductive interconnects may include a wettable metal layer 609. The wettable metal layer provides a surface for adhesion of a flowable conductive material 617, e.g., a fusible metal such as a solder, tin, eutectic composition, or conductive paste: e.g., material having a solder or other filling of conductive particles such as solder or silver-filled epoxy, among others. The wettable layer may be needed when the material composition of the lid or of an exposed surface of the lid is not wettable by such flowable conductive material, such as when the lid is primarily made of glass, ceramic, polymer, or a metal having a surface finished with one or more such materials, or in cases when the lid consists essentially of a metal, e.g., aluminum or copper which rapidly forms a native oxide.

The wettable metal layer 609 on the bond pads and through holes typically includes a diffusion barrier layer which includes a metal or metal compound or both which is deposited in contact with a base metal such as copper or aluminum. In an example, zinc, tungsten, titanium or various nitrides of tungsten or titanium can be used as the diffusion barrier layer. Typically, then, at least one layer including a metal wettable by the fusible or flowable conductive material is deposited to overlie the diffusion barrier layer. The wettable metal layer may include a diffusion barrier layer including zinc, over which layers of nickel and then gold are deposited, such as by electroless deposition. In an example, the thickness of the diffusion barrier layer is about 0.1 micron (μm), the thickness of the nickel layer is between about three and about five microns, and the thickness of the gold layer is about 0.1 microns.

The wettable metal layer 609 may be formed after depositing an initial layer of aluminum on walls of through holes 604, on bond pads 608, or both, such as by a sputtering process or various vapor deposition processes. Alternatively, such aluminum layer can be deposited by chemical electrodeposition or electroless deposition. A seed material including palladium or other material can be used in such deposition processes. When deposited by sputtering or other vapor deposition, silicon or copper or both may be incorporated into the deposited layer to help control the size of deposited grains and subsequent growth of the grains. Desirably, the aluminum layer is deposited at a stage of fabrication after a lid wafer including the lid 610 is joined to a device wafer which includes the chip 602. In an example, the aluminum layer deposited at this stage of fabrication may have a nominal thickness of about 5 microns (μm).

Desirably, the aluminum layer is deposited onto the bond pads and walls of the through holes after any surface oxides, e.g., native oxides, or other dielectrics or contaminants are removed from exposed surfaces of the bond pads. In one example, about 30% of the thickness of the deposited aluminum layer is removed by such cleaning process. Reverse bias sputtering, fast atom bombardment or other cleaning technique, among others, can be used to prepare the surface of the bond pads. In such way, the layer of deposited aluminum forms an ohmic connection with the bond pads.

In a particular embodiment, a quantity of conductive paste, e.g., solder paste, etc., may be applied to the wettable metal layer 609 before introducing solder into the through holes to form the conductive interconnects 612. The solder paste can be applied to the wettable layer 609 on the bond pads 608, such as by screening or stenciling from above the lid 610. In this way, the solder paste can bridge the gap between the front surface 601 of the chip and the inner surface of the lid. When the solder is applied through the outer surface of the lid by causing solder balls to come to rest in the through holes as described in the incorporated U.S. patent application Ser. No. 10/949,674, heating the substrate causes the solder of the solder balls to melt, wet the wettable metal layer 609 and merge with the flowing solder paste applied to the bond pads 608.

In a particular process which does not require the application of a solder paste, the gap can be bridged by making the wettable metal layer thicker. For example, the thickness of the wettable metal layer can be increased by depositing the nickel layer thereof to a greater thickness such as 10 to 20 microns, a thickness comparable to the height of the gap needed for many lidded chip packages.

A layer 614 including an adhesive overlies the front surface 601 of the chip between the chip 602 and the lid 610, an opening being provided in the layer such that a device region 616 of the chip is exposed. Away from the device region, an opening 606 is provided in the lid in which a secondary chip or element is mounted to the layer 614. A heat conducting element 620, which can be referred to variously as a heat spreader or thermal conductor, for example, is disposed between a rear surface 622 of the secondary element 618 and layer 614. In this way, the heat spreader 620 conducts heat away from the secondary element 618 into the base chip 602. First contacts 626 are provided at a front surface 624 of the secondary element and are conductively connected to second contacts 628 on a top surface 611 of the lid by bond wires 630.

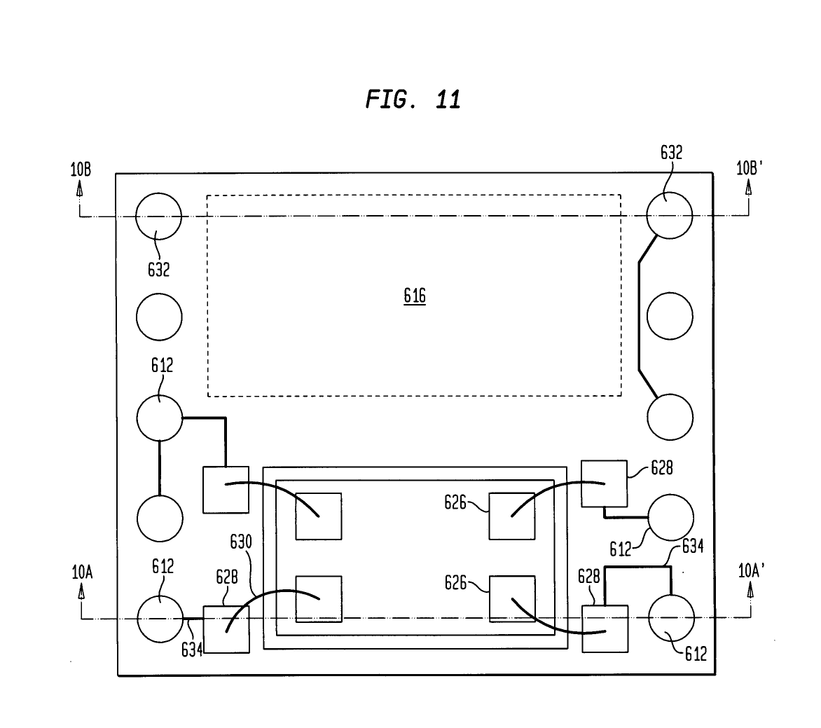

FIG. 11 depicts a corresponding top plan view of the lidded chip assembly 600, the location of the device region being indicated at 616. As best seen therein, the first contacts of the secondary element 618 are wire-bonded directly to the second contacts 628. In turn, the second contacts 628 are conductively connected by way of conductive traces 634 on the outer surface 611 (FIG. 10A) to surfaces of the conductive interconnects 612 at locations exposed at the exterior surface of the lid. The lidded chip assembly can then be placed with the lid 610 facing up and the base chip facing down toward the circuit panel, after which further bond wires are formed to conductively connect the first contacts 626 to the second contacts 628. Some of the contacts at the outer surface of the lid may not be connected to the first contacts 626 of the secondary element. Alternatively, solder bumps or balls, stud bumps or other vertically rising bumps (not shown) can be provided on the conductive interconnects 612 for interconnection of the lidded chip assembly to a face of a circuit panel (not shown) when the circuit panel has an opening for passage of light or other electromagnetic radiation at a frequency of interest.

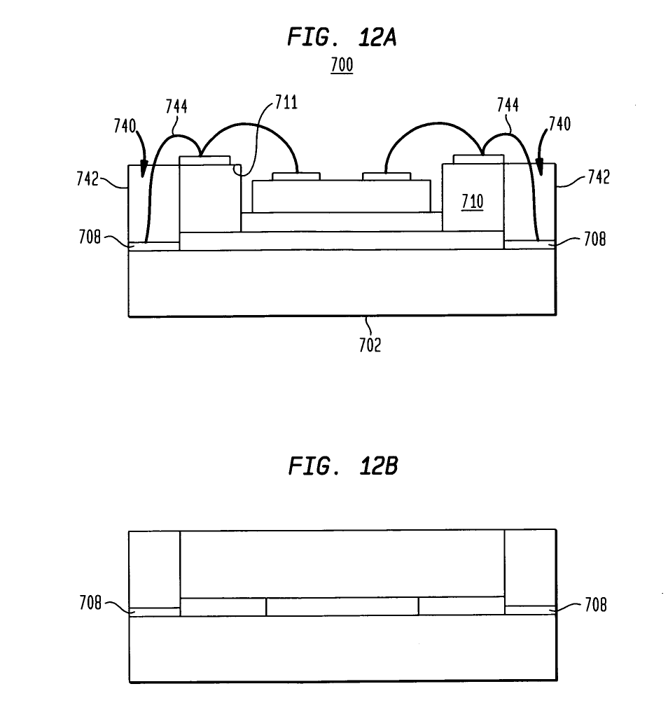

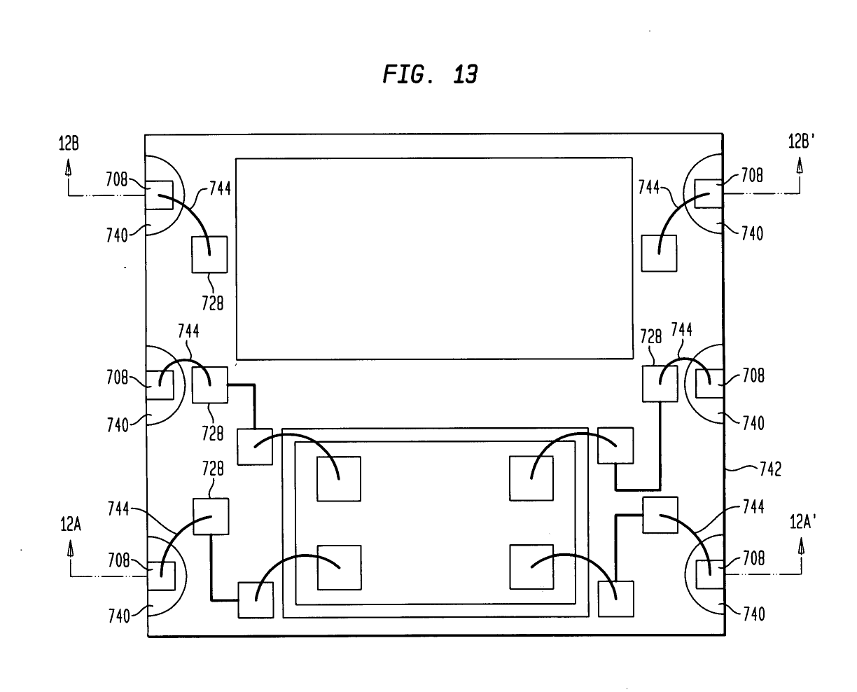

FIGS. 12A-B and 13 illustrate a lidded chip assembly 700 according to a variation of the embodiment shown in FIGS. 10A-B and 11. In this variation, recesses 740 are provided at the peripheral edges 742 of the lid 710, the recesses exposing a series of contacts 708 of the base chip 702. Details of a similar structure and methods of fabricating a similar lidded chip assembly are provided in commonly owned application Ser. No. 11/322,617 filed Dec. 30, 2005. As best seen in FIG. 13, the contacts 708 of the base chip are conductively connected to the third contacts on the outer surface 811 of the lid by way of bond wires 744.

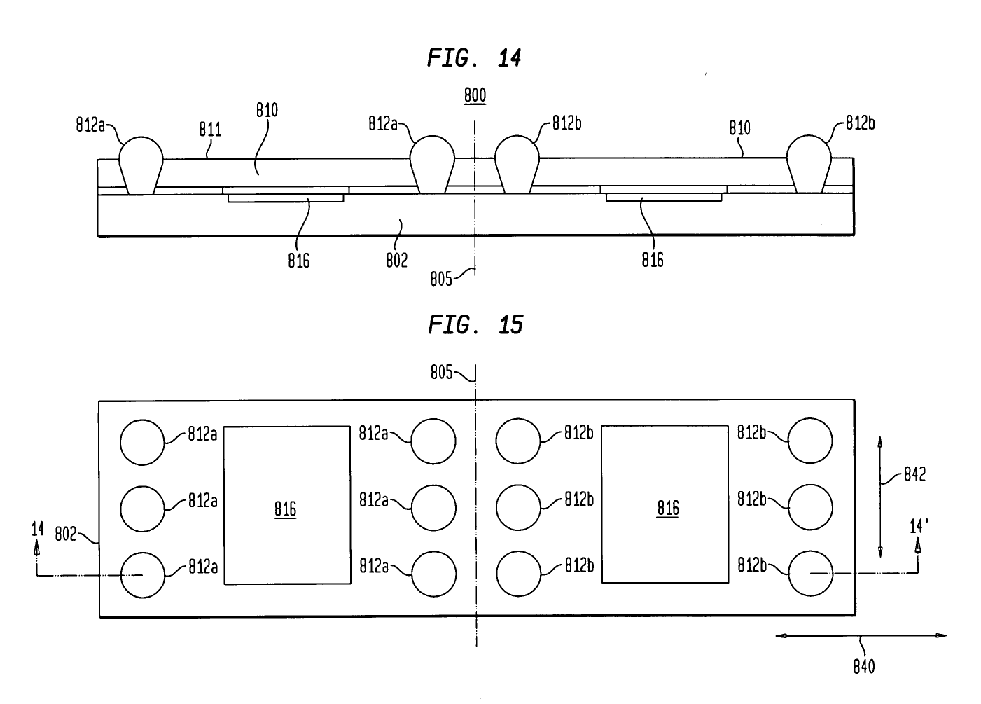

FIGS. 14-15 illustrate a variation of a lidded chip 800 assembly according to the above-described embodiment 600 (FIG. 10) in which multiple optoelectronic device regions 816a, 816b, e.g., imaging devices such as charge-coupled device arrays (“CCD” arrays) or the like are provided at the front surface 801 of one chip 802 or semiconductor element, e.g., portion of a wafer. The chip 802 may include a single chip or may be a portion of a wafer included a plurality of chips which remain attached to each other at peripheral edges, e.g., lanes between them. While the assembly illustrated in FIGS. 14-15 is shown having two optoelectronic device regions, it can, of course, include more. The multiple optoelectronic device regions 840 may be disposed next to each other in either a first direction as illustrated in FIG. 15, or alternatively, in a second direction 842 transverse to the first direction. In another variation, multiple optoelectronic device regions may be disposed next to each other in the first direction and multiple device regions may be disposed next to each other in the second direction as well such that the lidded chip assembly includes three or more such optoelectronic device regions.

In this embodiment, a single lid 810 overlies each of the device regions 816a, 816b for protection against dust or other contamination. Conductive interconnects 812a, 812b extend upward through through holes in the lid 810, the conductive interconnects being exposed at the outer surface 811 of the lid. Desirably, external electrical interconnection for a first device region 816a is available through conductive interconnects 812a and external electrical interconnection for a second device region 816b is available through conductive interconnects 812b.

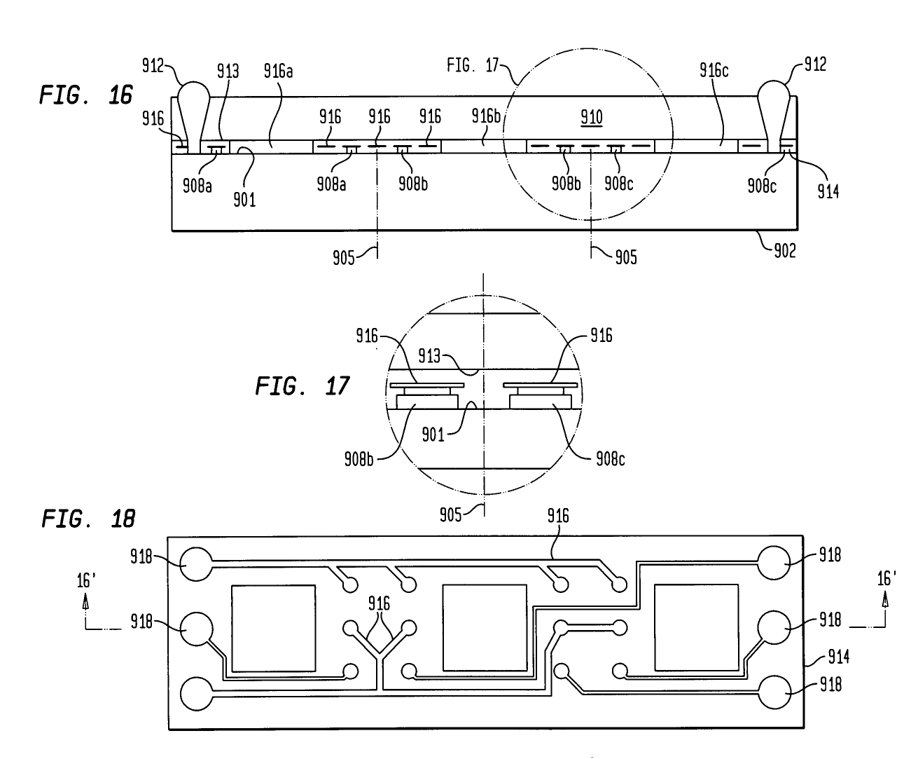

FIG. 16 illustrates a lidded chip assembly in accordance with a variation of the embodiment illustrated in FIGS. 14-15. As shown therein, a chip 902 or semiconductor element includes three optoelectronic device regions 916a, 916b, 916b adjacent to each other in a horizontally extending direction parallel to the front surface 901 of the chip 902. Each of the optoelectronic device regions may belong to a single chip which remains attached to other chips at dicing lanes 905. External conductive interconnection to the chip 902 is provided through conductive interconnects 912 which extend from some of the contacts 908a, 908c upward through through holes in the lid 910. However, as depicted in FIG. 16, at least some of the contacts 908a, 908b, 908c at the front surface 901 of the chip are covered by the lid 910 such that they are not directly accessible from locations external to the lid.

As shown in FIG. 16 and as best seen in FIGS. 17 and 18, in the case of these contacts, external conductive interconnection is provided through a series of conductive traces 916 of a metal layer provided in or on a dielectric element 914. The dielectric element 914 with metal layer thereon is interposed between the front surface 901 of the chip and a confronting surface 913 of the lid (FIGS. 16-17). The conductive traces extend from the contacts 908a, 908b, 908c of the chip to pads 918 contacted by the external conductive interconnects 912. Windows 920, i.e., openings, are provided in the dielectric element 914 at locations which correspond to the locations of the device regions 916a, 916b, 916c of the chip. The conductive traces 916 have pads joined to the contacts 908a, 908b, 908c via solder, conductive paste or other conductive material, for example.

The conductive interconnects 912 can be formed, for example, by a process such as that described in commonly owned application Ser. No. 10/949,674 (incorporated herein). As described in that application, masses of fusible material, e.g., solder, tin or eutectic composition are allowed to flow into the through holes after joining the lid to the chip with the dielectric element interposed between them. Alternatively, the conductive interconnects can be formed by other techniques such as, without limitation, plating or conductive paste screening, or a combination thereof.

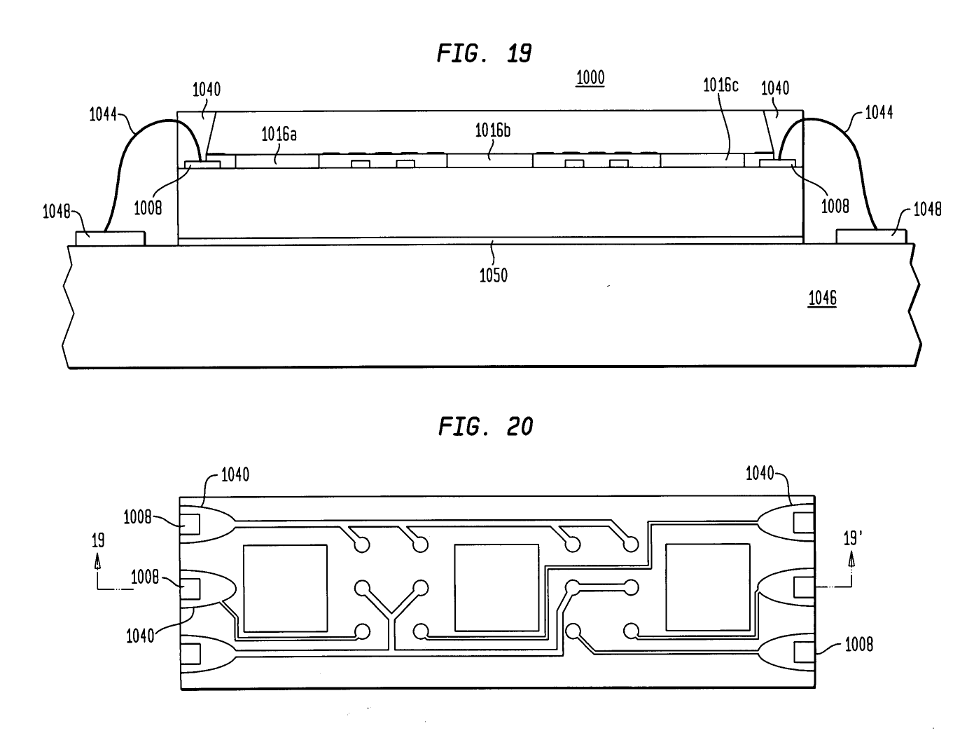

FIGS. 19-20 illustrate a similar lidded chip assembly 1000 which includes multiple device regions 1016a, 1016b, 1016c. Assembly 1000 varies from that shown in FIGS. 16-18 in that external conductive interconnection to the assembly is available through a series of bond pads 1008 exposed by recesses 1040 in the lid. Similar to the embodiment described above relative to FIG. 12, the recesses 1040 are provided at the peripheral edges 1042 of the lid 1010. The lidded chip assembly may be attached to a circuit panel 1046, e.g., through a die attach adhesive or other joining method and bond wires 1044 may be used connect the bond pads 1008 to terminals 1048 of a circuit panel 1046 or other element.

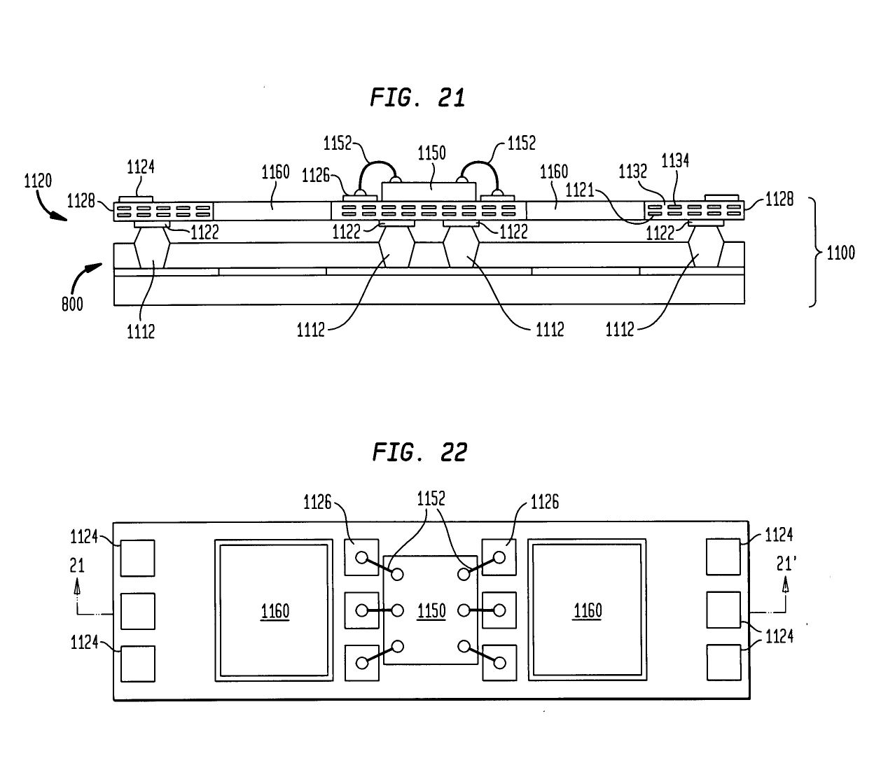

FIGS. 21-22 illustrate a higher level assembly 1100 which incorporates the multiple device lidded chip assembly 800 (FIGS. 14-15) which is shown and described above. In this embodiment, an interconnect element 1120 is disposed above the lidded chip assembly 800, the interconnect element 1120 including a dielectric element 1132 and a metal layer including conductive elements, e.g., conductive traces 1134 and contacts. The dielectric element may include a flexible dielectric material such as polyimide or other thermoplastic or polymeric material and be assembled with the lidded chip assembly in a manner similar to that used to join flexible “tape” type dielectric elements to other microelectronic devices such as chips. Alternatively, the dielectric element may be rigid or semi-rigid, including for example, a solid glass or solid ceramic substrate. In a particular embodiment, epoxy or other semi-rigid polymeric material can be utilized, alone or in combination with glass fiber in an FR-4 type or BT resin type of panel, for example.

The dielectric element has an inner surface 1121 confronting the lidded chip assembly 800 and an outer surface 1123 facing away from the lidded chip assembly. Windows 1160, i.e., openings extending through the dielectric element from the inner surface to the outer surface, are provided for passage of light or other electromagnetic signal energy to device regions of the lidded chip assembly.

The contacts include inner contacts 1122 at the inner surface which are joined to conductive interconnects 1112 of the lidded chip assembly 800. The interconnect element 1120 further includes outer contacts 1124 at the outer surface available to provide conductive interconnection to a circuit panel, such as through bond wires (not shown) from those contacts to terminals of a circuit panel, similar to the terminals 1048 of the circuit panel 1046 shown in FIG. 19. Such outer contacts 1124 may be disposed, for example, at or near peripheral edges 1128 of the interconnect element. In addition, second contacts 1126 on the outer surface of the interconnect element can be conductively connected to another element 1150, e.g., one or more active devices, passive devices, chips or a combination thereof, by way of bond wires 1152. Desirably, the inner contacts, outer contacts and second contacts are conductively connected by way of the conductive traces 1132.

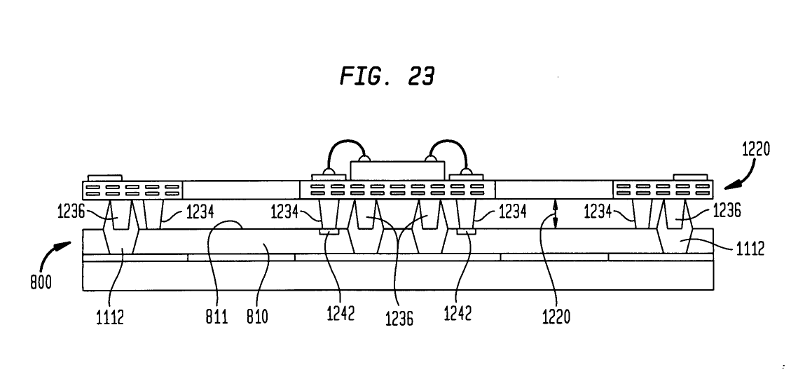

FIG. 23 illustrates a variation of above-described assembly (FIGS. 21-22) in which a series of conductive posts 1236 extend downwardly from the interconnect element 1220 and contact fusible conductive masses of the conductive interconnects of the lidded chip assembly 800. The conductive posts are provided in place of inner contacts 1124, e.g., lands as shown on interconnect element 1120 (FIG. 21). In this way, conductive interconnection is established between the interconnect element 1220 and the lidded chip the assembly. Other conductive posts 1234 serve to locate the interconnect element 1220 at a desired distance 1240 from the outer surface 811 of the lid 810. Optionally, the conductive posts 1234 may also provide conductive interconnection between the interconnect element and conductive features, e.g., traces or pads 1242 exposed at the outer surface of the lid.

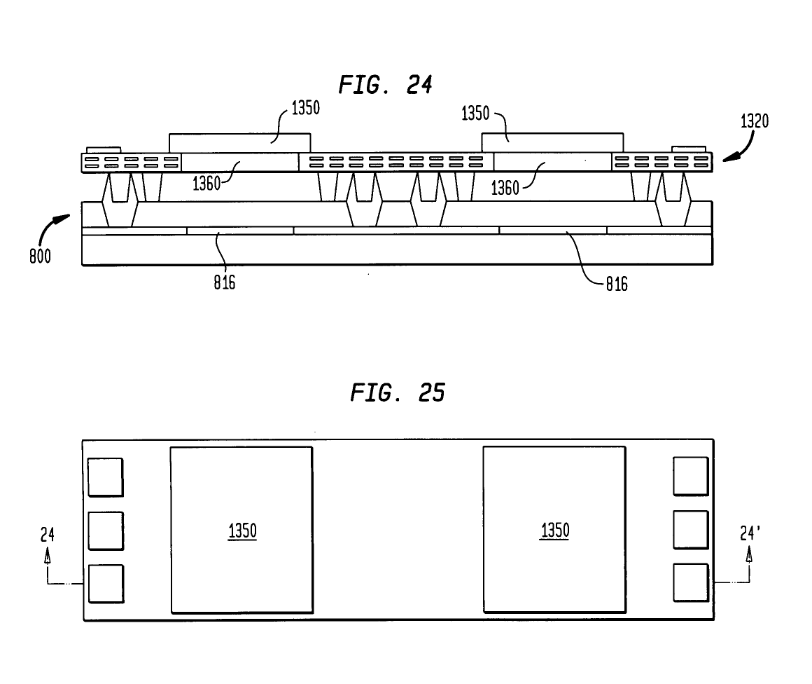

In a further variation (FIGS. 24-25), the interconnect element 1320 may include optical elements 1350, e.g., refractive or diffractive element, a combination thereof, a filter, mirror, partial mirror, etc. The optical elements may be used in conjunction with optoelectronic devices 816, e.g., imaging devices within the lidded chip assembly 800. As shown in FIGS. 24-25, the optical elements can be provided, for example, at an outer surface 1322 of the interconnect element such that they overlie the openings 1360 therein. Alternatively, the optical elements can be provided at the inner surface 1324 of the interconnect element. As further shown, the additional microelectronic element 1150 (FIGS. 21-22) need not be present.

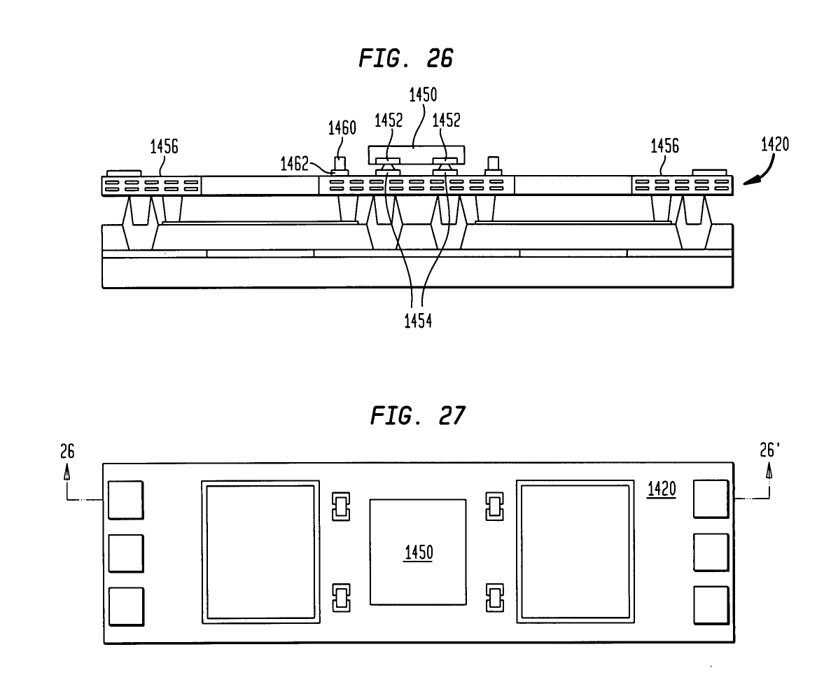

In a further variation, a microelectronic element 1450 (FIGS. 26-27), e.g., a chip including active devices, passive devices or a combination thereof, has bond pads 1452 facing and conductively connected to contacts 1454 at the outer surface 1456 of the interconnect element 1420. Additional devices 1460, e.g., passive devices, which can be discrete devices or otherwise, may be mounted to other contacts 1462 at the outer surface 1456.

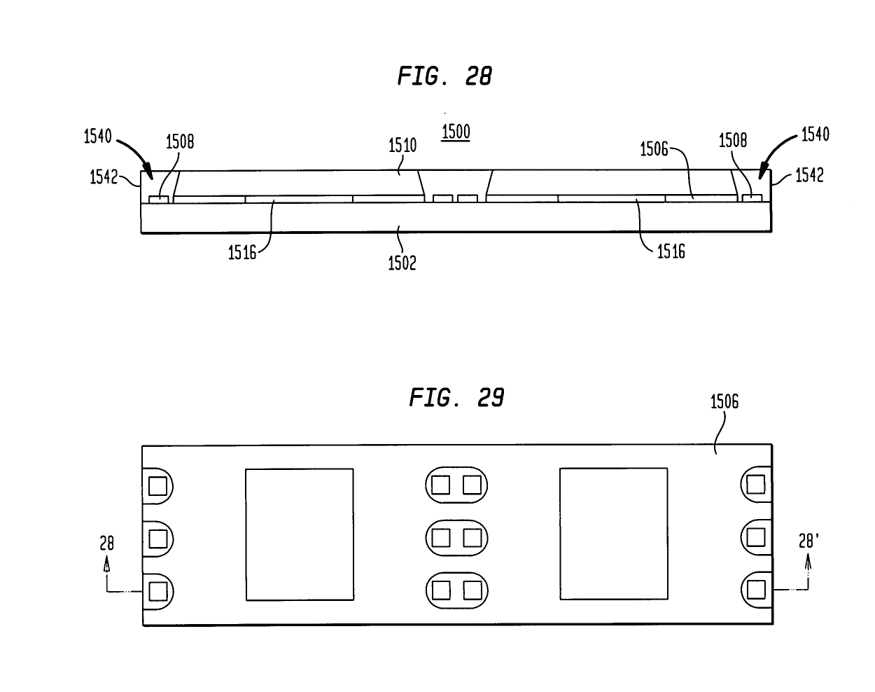

FIGS. 28-29 illustrate a lidded semiconductor element assembly 1500 according to another embodiment in which the semiconductor element 1502 also includes multiple optoelectronic device regions 1516. The semiconductor element 1502 is assembled with a lid 1510 overlying the front surface 1501 and a supporting layer 1506 including an adhesive disposed between the semiconductor element and the lid. The supporting layer 1506 includes windows, i.e., through openings, which are sized and positioned to coincide with the device regions 1516 of the semiconductor element 1502.

Similar to the embodiment described above with respect to FIGS. 19-20, recesses 1540 are provided in the lid and the supporting layer 1506 at the edges 1542 of the lid. Contacts, e.g., bond pads 1508 of the chip are exposed by the recesses. However, in the lid further includes through holes 1550 each of which is sized and shaped to expose one or more contacts of the chip. In the example illustrated in FIGS. 28-29, a pair of bond pads, are exposed by each through hole 1550. One of the bond pads can belong, i.e., be electrically connected to a first one of the device regions 1516 and the other bond pad belong to the second one of the device regions 1516. Alternatively, both bond pads exposed within one through hole can belong to the same one of the device regions 1516.

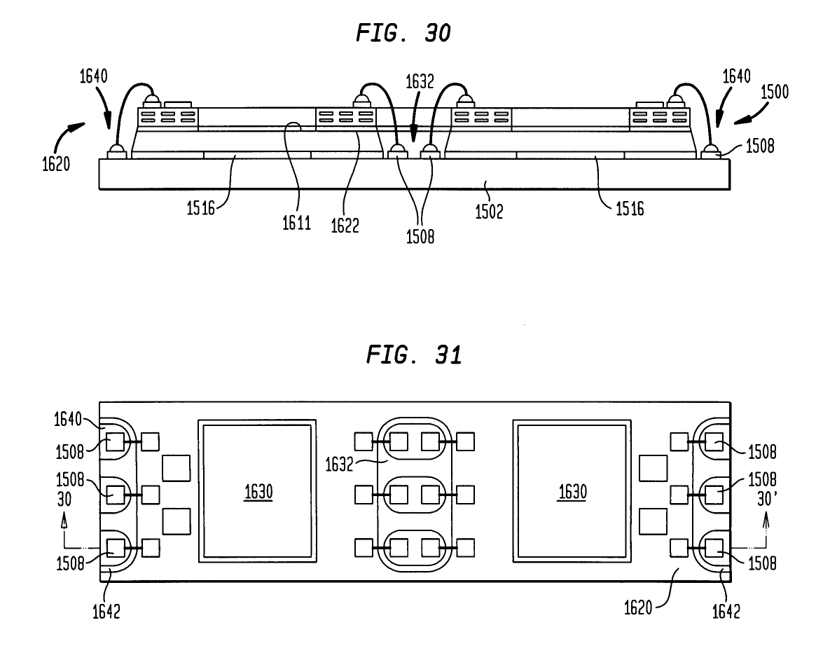

FIGS. 30-31 illustrate a higher level package assembly 1600 according to another embodiment which includes the lidded semiconductor element assembly 1500 described above with reference to FIGS. 28-29. Similar to that described above with reference to FIGS. 21-22, the package assembly 1600 also includes an interconnect element 1620 having windows 1630, i.e., through openings. The windows are sized and positioned to allow light or other electromagnetic radiation to be transmitted to or from the device regions 1516 of the lidded semiconductor element assembly. In addition, the interconnect element 1620 includes recesses 1640 which expose bond pads 1508 of the lidded chip assembly adjacent to edges 1542 of the assembly. The interconnect element further includes recesses 1632 which expose bond pads 1518 which are not at the edges of the assembly. Desirably, the interconnect element 1620 is bonded to a top surface 1611 of the lidded semiconductor element assembly 1500 by an adhesive 1622. The adhesive desirably overlies areas of the semiconductor element 1502 which do not coincide with the device regions 1516. Bond wires 1644 conductively connect the bond pads 1508 of the semiconductor element

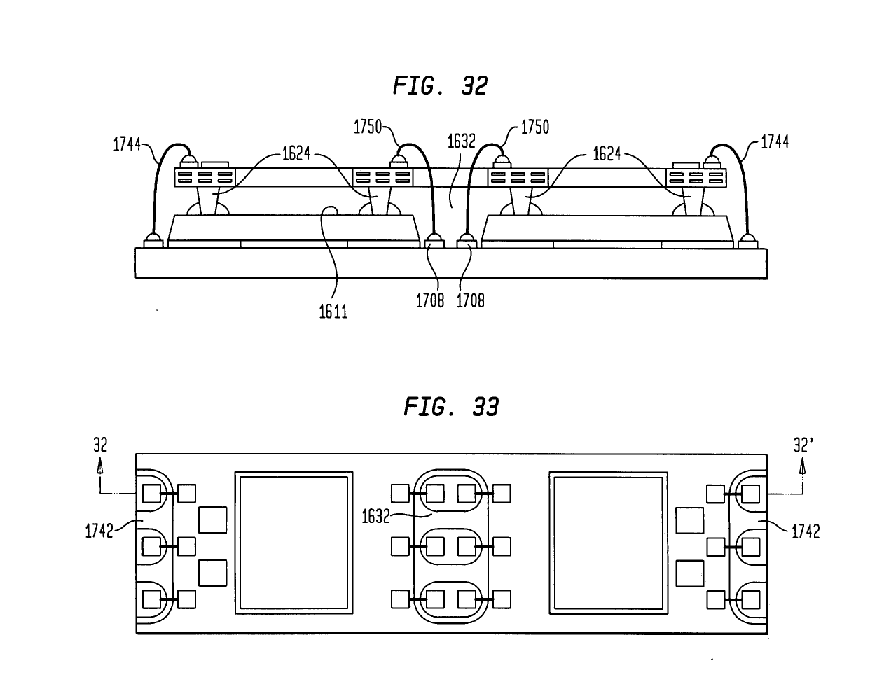

Another variation is illustrated in FIGS. 32 and 33 in which the interconnect element 1720 includes conductive posts 1624 which extend downwardly towards the top surface 1611 of the lid 1510. The conductive posts 1624 serve to locate the interconnect element 1720 at a desired distance 1722 from the top surface 1611 of the lid. Bond wires 1744 conductively connect first contacts 1746 provided at the outer surface 1748 of the interconnect element to bond pads 1508 adjacent to edges 1742 of the semiconductor element. Other bond wires 1750 connect second contacts 1752 at the outer surface 1748 to other bond pads 1508 through the opening 1632. In a particular embodiment, the conductive posts may be conductively connected to traces 1716 within the interconnect element to carry current, e.g., power, ground or signals to and from conductive pads which may be provided at the top surface of the lid.

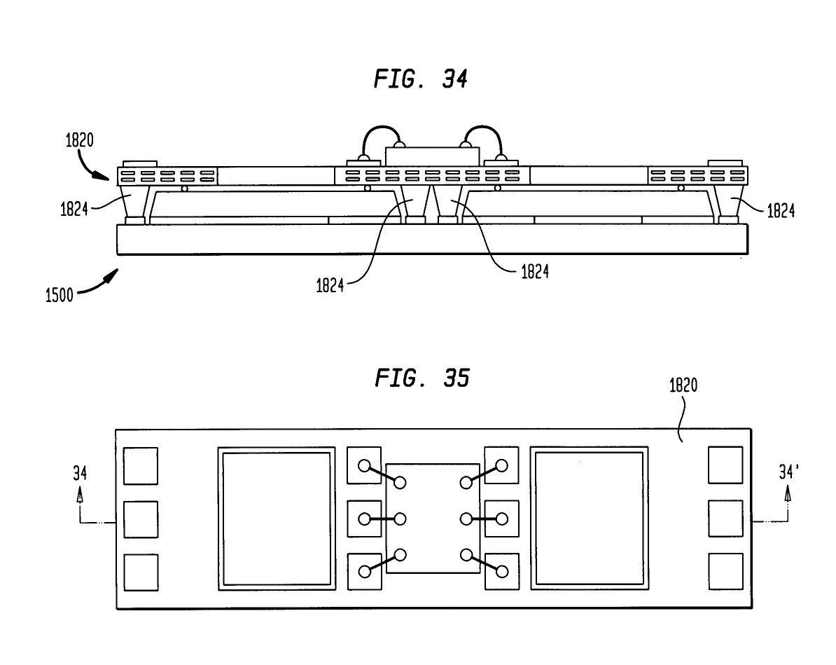

FIGS. 34-35 illustrate a further variation in which conductive posts 1824 extending downwardly from the interconnect element 1820 provide conductive interconnection between the lidded semiconductor element assembly 1500 and the interconnect element 1820. Here, except for the conductive posts 1824 which replace the contacts 1122 (FIGS. 21-22), the interconnect element 1820 appears very similar to the interconnect element 1120 shown and described above with respect to FIGS. 21-22.

As these and other variations and combinations of the features discussed herein can be utilized without departing from the present invention, the foregoing description of the preferred embodiments should be taken by way of illustration rather than by way of limitation of the invention as defined by the claims.

1. A lidded chip, comprising:
a chip having a major surface and a plurality of first chip contacts exposed at the major surface;
a lid overlying the major surface, the lid having a downwardly facing inner surface, an upwardly facing outer surface, and a plurality of openings extending between the inner and outer surfaces;
a chip carrier having an inner surface confronting the major surface and an outer surface confronting the inner surface of the lid, the chip carrier including a plurality of first carrier contacts conductively connected to the first chip contacts, a plurality of second carrier contacts extending upwardly at least partially through the openings in the lid, and a plurality of traces extending between the first and second carrier contacts.

2. A lidded chip as claimed in claim 1, wherein the chip includes an active region having an optoelectronic device, and the lid is at least partially transmissive to frequencies of interest to the optoelectronic devices.

3. A lidded chip as claimed in claim 2, wherein the chip carrier has an opening permitting transmission of radiation at frequencies of interest between the major surface and a space above the chip carrier.

4. A lidded chip as claimed in claim 3, further comprising a standoff structure supporting an inner surface of the lid from the major surface to define a cavity between the inner and major surfaces.

5. A lidded chip as claimed in claim 1, wherein lateral dimensions of the major surface of the chip are at least substantially the same as lateral dimensions of the lidded packaged chip.

6. A lidded chip as claimed in claim 1, wherein the second carrier contacts include metallic posts such that tips of the posts protrude above the outer surface of the lid.

7. An assembly including the lidded chip as claimed in claim 1, further comprising a circuit panel having terminals conductively joined to the exposed tips of the posts.

8. A lidded chip as claimed in claim 1, wherein the lid has an inner surface bonded to the outer surface of the chip carrier.

9. A lidded chip, comprising:
a chip having a major surface, an active region including an optoelectronic device aligned with the major surface and a plurality of contacts exposed at the major surface;
a lid overlying the active region, the lid having an inner surface confronting the major surface of the chip, an outer surface remote from the inner surface and a plurality of through holes extending between the inner and outer surfaces;
a plurality of conductive package interconnects extending at least partially through the through holes; and
an interconnection element including horizontal metal elements connected to the package interconnects and metal posts connected to the horizontal metal elements, the interconnection element being disposed between the lid and the major surface, the horizontal metal elements extending along the inner surface of the lid, wherein the metal posts interconnect the horizontal metal elements to the contacts on the chip.

10. A lidded chip as claimed in claim 9, wherein the horizontal metal elements include conductive traces.

11. A lidded chip, comprising:
a chip including an active region having an optoelectronic device, the chip having a major surface, edges extending away from the major surface and a plurality of contacts exposed at the major surface;
a lid overlying the chip, the lid having an inner surface confronting the major surface of the chip; and
an interconnection element including a dielectric layer, lands exposed beyond the edges of the chip, conductive traces extending from the lands along the dielectric layer, and metal posts conductively connecting the conductive traces to the contacts on the chip.

12. The lidded chip as claimed in claim 11, further comprising conductive metal bumps extending from the lands away from the inner surface of the lid.

13. A lidded chip, comprising:
a chip having a major surface, an active region including an optoelectronic device at the major surface and a plurality of chip contacts at the major surface;
a lid overlying the active region, the lid having an inner surface confronting the major surface of the chip and an outer surface remote from the inner surface;
a plurality of package interconnects exposed at an exterior surface of the lidded chip;
an interconnection element disposed between the inner surface of the lid and the major surface of the chip, the interconnection element including horizontal metal elements in conductive communication with the contacts and the package interconnects.

14. A lidded chip as claimed in claim 13, wherein the chip includes a plurality of the active regions and the interconnection element includes a plurality of openings aligned with the active regions.

15. A lidded chip as claimed in claim 13, wherein the lid includes through holes extending between the inner and outer surfaces and the package interconnects extend from at least some of the chip contacts at least partially through the through holes.

16. A lidded chip as claimed in claim 13, wherein at least some chip contacts are exposed beyond edges of the lid and the package interconnects include the at least some exposed chip contacts.

17. A lidded chip as claimed in claim 13, wherein at least some chip contacts are exposed within recesses in edges of the lid and the package interconnects include the at least some exposed chip contacts.

18. A lidded chip as claimed in claim 14, wherein the lid includes through holes extending between the inner and outer surfaces and the package interconnects are disposed adjacent to peripheral edges of the chip and extend from at least some of the chip contacts at least partially through the through holes.

19. A lidded microelectronic assembly, comprising:
a microelectronic element having a major surface, a first active region and a second active region at the major surface, first conductive pads conductively connected to the first active region, and second conductive pads conductively connected to the second active region;
a lid overlying the first and second active regions, the lid having an inner surface confronting the major surface, an outer surface remote from the inner surface and a plurality of through holes extending between the inner and outer surfaces;
a plurality of package interconnects extending from the first and second conductive pads at least partially through the through holes; and
an interconnect element overlying the lid including a dielectric element having a first surface confronting the lid, a second surface remote from the first surface, a plurality of first contacts at the first surface joined to the plurality of package interconnects, a plurality of second contacts exposed at the second surface, and a plurality of conductive traces extending along the first surface.

20. A lidded microelectronic assembly as claimed in claim 19, wherein the conductive traces and the package interconnects connect the first conductive pads with the second conductive pads.

21. A lidded microelectronic assembly as claimed in claim 19, wherein the package interconnects include metallic posts extending downwardly from the first surface.

22. A lidded microelectronic assembly as claimed in claim 19, further comprising a second microelectronic element having third contacts, the third contacts conductively connected to the second contacts.

23. A lidded microelectronic assembly as claimed in claim 22, further comprising bond wires, the bond wires conductively connecting the third contacts to the second contacts.

24. A lidded microelectronic assembly as claimed in claim 22, wherein a front face of the second microelectronic element confronts the second surface of the interconnect element, further comprising a fusible metal conductively connecting the second and third contacts.

25. A lidded microelectronic assembly as claimed in claim 19, wherein the first and second active regions include optoelectronic devices and the lid is at least partially transmissive to radiation at frequencies of interest to the optoelectronic devices.

26. A lidded microelectronic assembly as claimed in claim 25, wherein the optoelectronic devices in at least one of the first or second active regions includes an imaging sensor.

27. A lidded microelectronic assembly as claimed in claim 26, further comprising an optical element aligned with at least one of the first or second active regions.

28. A lidded microelectronic assembly as claimed in claim 19, wherein the lid includes openings aligned with the first and second active regions.

29. A lidded microelectronic assembly, comprising:
a microelectronic element having a major surface, a first active region and a second active region at the major surface, first conductive pads conductively connected to the first active region, and second conductive pads conductively connected to the second active region;
at least one lid overlying the first and second active regions, the lid having an inner surface confronting the major surface, an outer surface remote from the inner surface and at least one channel extending between the inner and outer surfaces, the channel exposing the first conductive pads and the second conductive pads;
an interconnect element overlying the lid including a dielectric element having a first surface remote from the lid, a second surface confronting the lid, a plurality of first contacts conductively connected to the first and second conductive pads, a plurality of second contacts, and a plurality of conductive traces extending parallel to the first surface, the conductive traces connecting the first and second contacts.

30. A lidded microelectronic assembly as claimed in claim 29, wherein the first and second contacts are exposed at the first surface, the lidded microelectronic assembly further comprising bond wires, the bond wires conductively connecting the first contacts to the first and second conductive pads.

31. A lidded microelectronic assembly as claimed in claim 29, further comprising locating features protruding downwardly between the second surface of the interconnect element and the outer surface of the lid.

32. A lidded microelectronic assembly as claimed in claim 30, wherein the locating features include metallic posts.

33. A lidded microelectronic assembly as claimed in claim 30, wherein the locating features are bonded to the outer surface of the lid.

34. A lidded microelectronic assembly as claimed in claim 30, wherein the first contacts include conductive features extending downwardly between the second surface and the first and second conductive pads.

35. A lidded microelectronic assembly as claimed in claim 30, wherein the first contacts include metallic posts.

36. A lidded microelectronic assembly, comprising:
a first microelectronic element having a major surface, an active region at the major surface and first conductive pads exposed at the major surface;
a lid overlying the active region, the lid having an inner surface confronting the major surface, an outer surface remote from the inner surface, a plurality of through holes extending between the inner and outer surfaces, and an opening extending between the inner and outer surfaces;
a plurality of conductive interconnects extending upwardly from the conductive pads at least partially through the through holes; and
a second microelectronic element having a rear face confronting the first microelectronic element within the opening, the second microelectronic element having a front face remote from the rear face and second conductive pads at the front face, the second conductive pads being conductively connected to the conductive interconnects.

37. A lidded microelectronic assembly as claimed in claim 35, further comprising lid contacts exposed at the outer surface of the lid, conductive traces connecting the lid contacts to the conductive interconnects, and bond wires conductively connecting the second conductive pads to the lid contacts.

38. A lidded microelectronic assembly, comprising:
a first microelectronic element having a major surface, an active region at the major surface and first conductive pads exposed at the major surface;
a lid overlying the active region, the lid having an inner surface confronting the major surface, an outer surface remote from the inner surface and edges extending between the inner and outer surfaces, the lid further including lid contacts exposed at the outer surface, an opening extending between the inner and outer surfaces and a plurality of recesses in at least one edge exposing at least ones of the first conductive pads; and
a second microelectronic element having a rear face confronting the first microelectronic element within the opening, a front face remote from the rear face and second conductive pads at the front face, the first and second conductive pads being conductively connected to the lid contacts.

39. A lidded microelectronic assembly as claimed in claim 37, further comprising bond wires, the bond wires conductively connecting the first and second conductive pads to the lid contacts.

40. A lidded microelectronic assembly as claimed in claim 38, wherein the lid contacts include first lid contacts and second lid contacts, and the bond wires include first bond wires and second bond wires, wherein the first bond wires conductively connect the first conductive pads to the first lid contacts and the second bond wires conductively connect the second conductive contacts to the second lid contacts, the lidded microelectronic assembly further comprising conductive traces connecting the first lid contacts to the second lid contacts.

41. A method of fabricating a lidded packaged chip, comprising:
assembling a chip carrier with a semiconductor chip to form a chip carrier assembly such that the chip carrier overlies a major surface of the chip and plurality of first chip contacts of the chip are conductively connected to a plurality of first carrier contacts of the chip carrier, the chip carrier including a plurality of second conductive contacts protruding above a surface of the chip carrier remote from the chip; and
mounting a lid to the chip carrier assembly such that tips of the plurality of second conductive contacts protrude upwardly through openings in the lid and are exposed above an outer surface of the lid remote from the chip carrier.

42. The method as claimed in claim 40, wherein the step of mounting the lid to chip carrier assembly includes supporting an inner surface of the lid a predetermined distance above the major surface of the chip.

43. The method as claimed in claim 40, wherein the second carrier contacts include metallic posts such that tips of the posts protrude above the outer surface of the lid.

44. The method as claimed in claim 42, wherein the chip carrier includes a dielectric layer defining a major surface, each post of the plurality of posts having a base proximate to the major surface and a tip remote from the base, the base occupying a first area in the plane of the major surface, and the tip occupying a second area in a plane parallel to the major surface, the first area being greater than the second area, and each of the openings occupying a third area greater than the second area and less then the first area, wherein the step of mounting the lid to the chip carrier assembly includes press-fitting the posts into the openings in the lid.

45. The method as claimed in claim 43, further comprising bonding a surface of the chip carrier to an inner surface of the lid with an adhesive.

46. The method as claimed in claim 44, wherein the surface of the chip carrier is bonded to the inner surface of the lid before the chip carrier is assembled together with the chip.
